(19) United States
(12) Patent Application Publication
(10) Pub. No.: US 2009/0127721 A1
(43) Pub. Date: May 21, 2009

(54) SEMICONDUCTOR INTEGRATED CIRCUIT DEVICE

(75) Inventor: Toshio ISONO, Kanagawa (JP)

Correspondence Address: SUGHRUE MION, PLLC, 2100 PENNSYLVANIA AVENUE, N.W., SUITE 800, WASHINGTON, DC, 20037, US

(73) Assignee: NEC Electronics Corporation, Kanagawa (JP)

(21) Appl. No.: 12/270,469

(22) Filed: Nov. 13, 2008

(30) Foreign Application Priority Data
Nov. 16, 2007 (JP) 2007-297615

(51) Int. Cl. H01L 23/528

(52) U.S. Cl. 257/786; 257/E23.151

(57) ABSTRACT

A semiconductor integrated circuit comprises a first and second common wiring layers common to a plurality of types of products and independent of a user circuit, a customized layer provided between the first common wiring layer and the second common wiring layer and which is configured to form the user circuit. The second common wiring layer is formed above an upper layer of the first common wiring layer, and an universal logic cell is wired to the first and second common wiring layers and the customized layer. A power supply wiring, which is connected to a power supply pad, which is connected to an external power supply, is formed through the second common wiring layer, and the power supply wiring is formed in the same layer as the power supply pad and extends to an internal circuit area in which the universal logic cell is formed.

### BACKGROUND

1. Field of the Invention

The present invention relates to a semiconductor integrated circuit device, and more particularly, to a semiconductor integrated circuit device including a common wiring layer which is common to a plurality of types of products without depending on user circuits and a customize layer forming a user circuit.

2. Description of Related Art

Various techniques of developing semiconductor integrated circuit devices have been suggested including a technique called structured ASIC (Application Specific Integrated Circuit). The structured ASIC includes a common wiring layer that is common to a plurality of types of products without depending on user circuits, and a customize layer forming the user circuit provided on the common wiring layer. Then a plurality of functional cells are formed in advance by the common wiring layer and an underlying basic element layer (transistor layer), and these functional cells are interconnected by the customize layer, so as to realize the user circuit.

According to this technique, a mask for forming the common wiring layer can be commonly used, which can reduce the development cost. Further, the functional cells can be formed by the common wiring layer in advance regardless of the user demand; which means the development period can be shortened.

Now, one example of the semiconductor integrated circuit device (hereinafter simply referred to as “semiconductor device”) of the master slice method including the structured ASIC will be described. FIG. 6 shows a top view of the semiconductor device, and FIG. 7 shows a cross sectional view taken along the line VII-VII′ of FIG. 6. As shown in the drawings, a plurality of pads 1 are formed in a peripheral region in four sides of the semiconductor chip 100. The input/output buffer region 20 is arranged inside the pads 1, and an internal circuit region 10 is further arranged inside the input/output buffer region 20. An input/output buffer peripheral power supply lines 2 are formed in the same layer as the pads 1. The input/output buffer peripheral power supply lines 2 are formed in the input/output buffer region 20. A structure of aligning basic cells, which are called input/output (IO) slots, is formed in the input/output buffer region 20. The input/output buffer peripheral power supply lines 2 supply power equally to all these IO slots.

Further, an internal circuit is formed in the internal circuit region 10, and a customize layer 102 is formed on a common wiring layer 101.

The input/output buffer peripheral power supply lines 2 are provided in the input/output buffer region 20 which is in the same layer as the pads 1, and internal power supply lines 41 to 44 are provided in the internal circuit region 10 of the common wiring layer 101. The internal power supply lines 41 to 44 are electrically connected to the pads 1 through vias in the peripheral region of the chip 100.

Although the internal power supply lines can be provided in the customize layer 102, it is typically provided in the common wiring layer 101 in order to provide larger number of wiring channels to the user or an area which can be interconnected by the user. However, since there is a need to arrange a wiring in internal block, a wiring in macro, a buried clock wiring, or a buried test circuit wiring also in the common wiring layer 101, it is difficult to arrange the internal power supply lines having enough width and enough number in the common wiring layer 101. Especially, in a situation where the power consumption is increased and there is a high demand of securing enough internal power supply lines along with the enhancement of performance and integration of the semiconductor device, this problem cannot be ignored. Further, it is required to arrange the internal power supply lines properly also from a viewpoint of signal integrity.

As shown in FIGS. 6 and 7, the internal power supply lines 41 to 44 are electrically connected to the pads 1 through vias in the peripheral region of the chip 100; therefore it is more difficult to form enough internal power supply lines across over the internal circuit region.

For example, according to Japanese Unexamined Patent Application Publication Nos. 2002-299452 and 5-48054, the input/output buffer peripheral power supply line is formed in the uppermost layer of the input/output buffer region of the chip. Therefore, the internal power supply patterns are formed through a metal which is in a lower layer than the input/output buffer peripheral power supply line.

### SUMMARY

However, when the pads and the internal power supply lines are connected through the lower-layer metal, it is difficult to use the IO slots in a region having the lower-layer metal. For example, if 20 power supply pads (20 pads for internal power supply (VDD) and 20 pads for ground (GND)) are needed for 1(W), 40 IO slots are wasted. Other related examples include Japanese Patent No. 3626044.

An exemplary aspect of an embodiment of the present invention is a semiconductor integrated circuit comprising a first common wiring layer common to a plurality of types of products and independent of a user circuit, a second common wiring layer common to a plurality of types of products and independent of the user circuit, and formed above an upper layer of the first common wiring layer, and a customized layer provided between the first common wiring layer and the second common wiring layer and which is configured to form the user circuit. An universal logic cell is wired to the first and second common wiring layers and the customized layer, a power supply wiring is formed through the second common wiring layer. A power supply wiring is connected to a power supply pad, and the power supply pad is connected to an external power supply. The power supply wiring is formed in the same layer as the power supply pad and extends to an internal circuit area in which the universal logic cell is formed.

According to the present invention, there is provided a semiconductor integrated circuit device including a common wiring layer and a customize layer, and the power supply wiring supplying the power to the internal circuit is formed in the same layer as the power supply pad in the common wiring layer arranged in the upper layer than the customize layer, and the power supply wiring is extended to the internal circuit region. Accordingly, it is possible to provide a semiconductor integrated circuit device capable to supplying the power to the internal circuit without wasting the IO slots.

### BRIEF DESCRIPTION OF THE DRAWINGS

The above and other exemplary aspects, advantages and features will be more apparent from the following description of certain exemplary embodiments taken in conjunction with the accompanying drawings, in which:

FIG. 1 is a top view of a semiconductor integrated circuit device according to one exemplary embodiment of the present invention;

FIG. 2 is a cross sectional view of the semiconductor integrated circuit device according to the exemplary embodiment of the present invention;

FIG. 3 is a plan view showing a structure of the semiconductor integrated circuit device according to the exemplary embodiment of the present invention;

FIG. 4 is a cross sectional view showing a structure of the semiconductor integrated circuit device according to the exemplary embodiment of the present invention;

FIG. 5 is a top view of the semiconductor integrated circuit device according to a second exemplary embodiment of the present invention;

FIG. 6 is a top view of a semiconductor integrated circuit device according to a related art; and

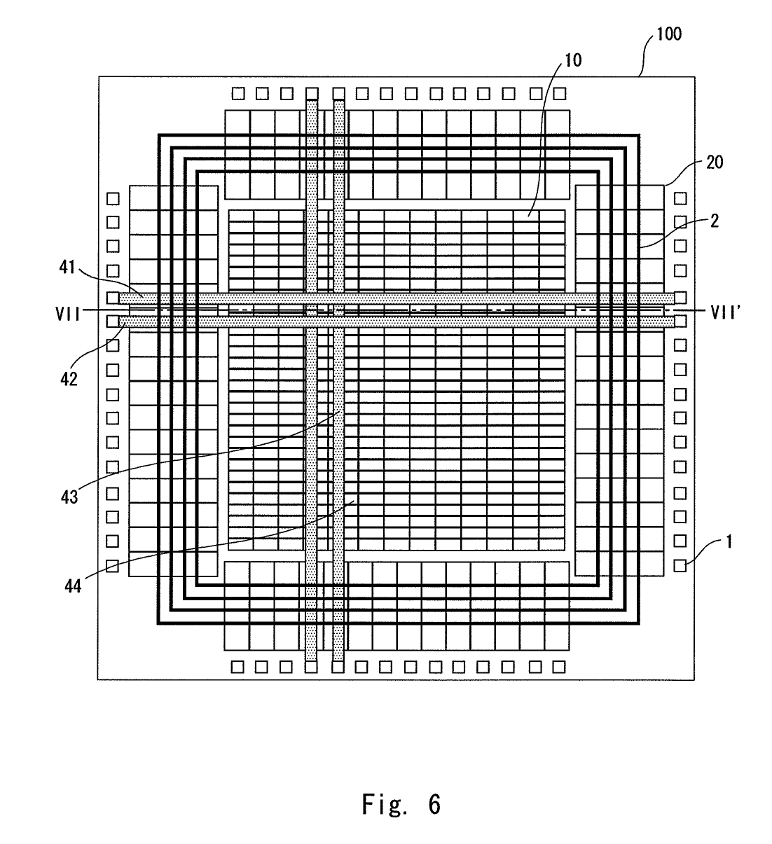

FIG. 7 is a cross sectional view of the semiconductor integrated circuit device according to the related art.

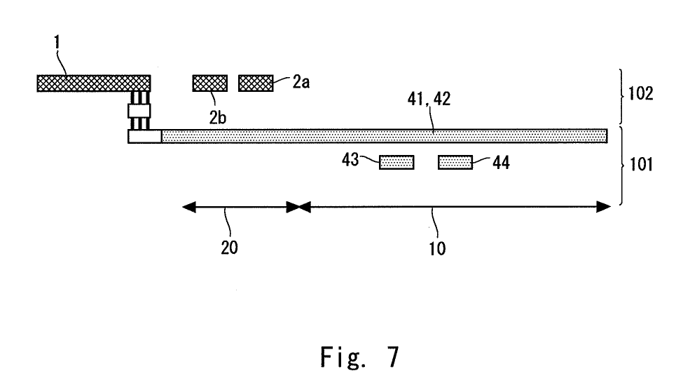

### DETAILED DESCRIPTION OF THE EXEMPLARY EMBODIMENTS

### First Exemplary Embodiment

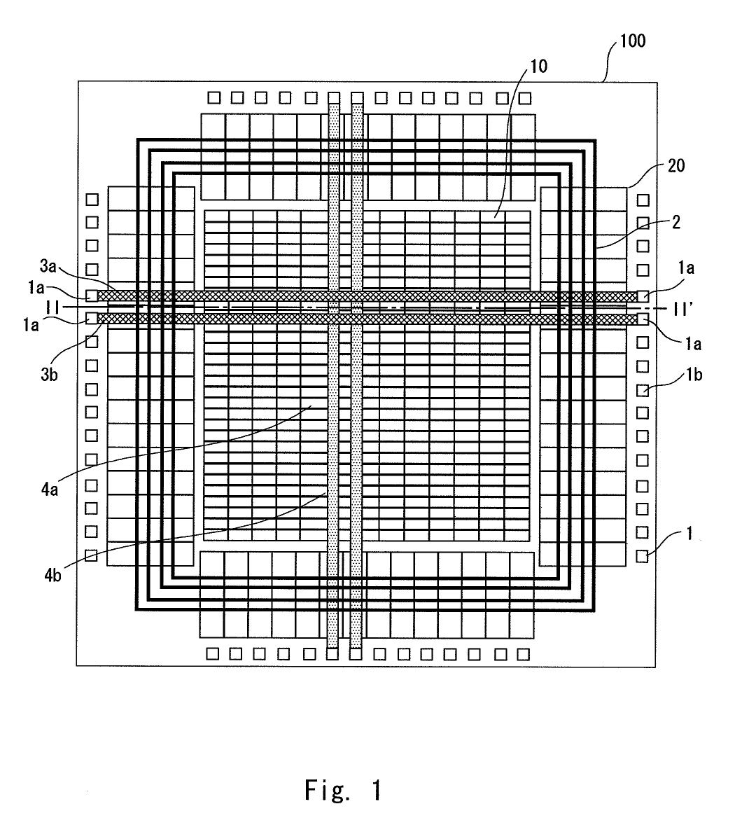

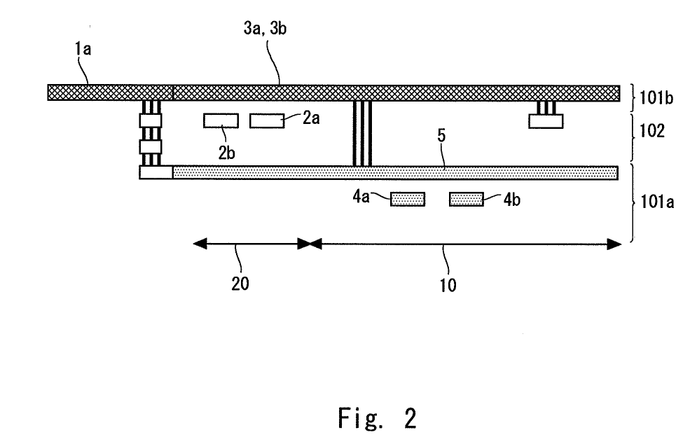

The structure of a semiconductor device according to the first exemplary embodiment of the present invention will be described with reference to FIGS. 1 and 2. FIG. 1 is a top view of the semiconductor device, and FIG. 2 is a cross sectional view taken along the line II-II′ of FIG. 1. As shown in the drawings, a plurality of pads 1 are formed in a peripheral region in four sides of a semiconductor chip 100. The pads 1 include power supply pads 1a and input/output pads 1b. The power supply pads 1a are connected to an external terminal by wire bonding, and power is supplied from outside through a wire. An input/output buffer region 20 is provided inside the pads 1, and an internal circuit region 10 is further provided inside the input/output buffer region 20.

An input/output buffer peripheral power supply lines 2 are formed in the input/output buffer region 20. A structure of aligning basic cells, which are called input/output (IO) slots, is formed in the input/output buffer region 20. The input/output buffer peripheral power supply lines 2 supply power equally to all these IO slots. In the semiconductor device according to the exemplary embodiment, the input/output buffer peripheral power supply lines 2 are provided not in an uppermost layer but in a customize layer 102. Accordingly, the power supply pads 1a and the internal power supply lines described later can be formed in the same layer. An internal circuit is formed in the internal region 10.

The semiconductor device according to the exemplary embodiment of the present invention is so-called structured ASIC, where a common wiring layer 101 and a customize layer 102 are formed on a basic element layer (not shown) in which basic element such as transistor is formed. The structured ASIC may be called platform ASIC.

In the semiconductor device according to the exemplary embodiment, a common wiring layer 101a is formed on the basic element layer (not shown), and the customize layer 102 is formed on the common wiring layer 101a. Further, a common wiring layer 101b is formed on the customize layer 102. The basic element layer and the common wiring layer 101 are typically called underlying layer, which can be designed in advance since it does not depend on the structure of the user circuit.

The common wiring layers 101a and 101b are formed by using common masks, and are metal wiring layers common to a plurality of types of products without depending on user circuits. The common wiring layer 101a is formed by three layers, and the common wiring layer 101b is formed by two layers, for example. The clock wiring and the test circuit are formed by the common wiring layer 101b, for example.

The wiring width of the common wiring layer 101a is narrower than the wiring width of the common wiring layer 101b. For example, the wiring width of the common wiring layer 101a is half or less than half of the wiring width of the common wiring layer 101b. The common wiring layer 101a according to the exemplary embodiment has the wiring width of 5 to 10 μm and the wiring thickness of 0.4 to 0.5 μm; while the common wiring layer 101b has the wiring width of 50 to 100 μm and the wiring thickness of 1.0 to 1.6 μm.

The common wiring layer 101b according to the exemplary embodiment is provided in the wiring layer including the uppermost layer. Internal power supply lines 3a and 3b are formed in the uppermost layer of the common wiring layer 101b. The internal power supply lines 3a and 3b are provided in the same layer to the power supply pads 1a and are electrically connected to the power supply pads 1a. The power supply pads 1a may have a cover layer made of Al or the like formed on the surface thereof. Also in this case, the internal power supply lines 3a and 3b are in the same layer as the power supply pads 1a. The internal power supply lines 3a and 3b are extended to the internal circuit region 10. Especially, the internal power supply lines 3a and 3b shown in FIG. 1 connect pads 1a provided in each two sides that are opposed to each other in the chip 100.

The internal power supply lines 3a and 3b and the internal circuit of the internal circuit region 10 are connected together through vias in any position in the internal circuit region 10.

Internal power supply lines 4a and 4b are formed in the common wiring layer 101a. The internal power supply lines 4a and 4b are connected to the power supply pads 1a through vias in the peripheral region outside the input/output buffer region 20, as is different from the internal power supply lines 3a and 3b. The power supply voltage supplied to the internal circuit by the internal power supply lines 4a and 4b is lower than the power supply voltage supplied to the IO slots by the input/output buffer peripheral power supply line 2.

A plurality of functional cells are formed in advance in the internal circuit region 10 by the underlying layer including the common wiring layer 101 and the basic element layer described above. The functional cells include universal logic cells. A plurality of functional cells are arranged in matrix form (array form) of rows and columns in the internal circuit region 10.

The customize layer 102 is formed by using a discrete mask and is a metal wiring layer for forming the user circuit. Nodes of the functional cells are formed in the uppermost layer of the common wiring layer 101, and the nodes are connected in the customize layer 102 so as to form the user circuit. The customize layer 102 is formed by two layers, for example.

In the semiconductor device according to the first exemplary embodiment, the internal power supply lines 3a and 3b are formed in the same layer as the power supply pad 1a in the common wiring layer 101b in the upper layer than the customize layer 102, and the internal power supply lines 3a and 3b are extended to the internal circuit region 10. Accordingly, the internal circuit can be supplied with the power without wasting the IO slots.

Further, since the internal power supply lines 3a and 3b are connected to couple the power supply pads 1a which are in the periphery of the opposing sides, the length of the wiring connected to the internal circuit can be reduced.

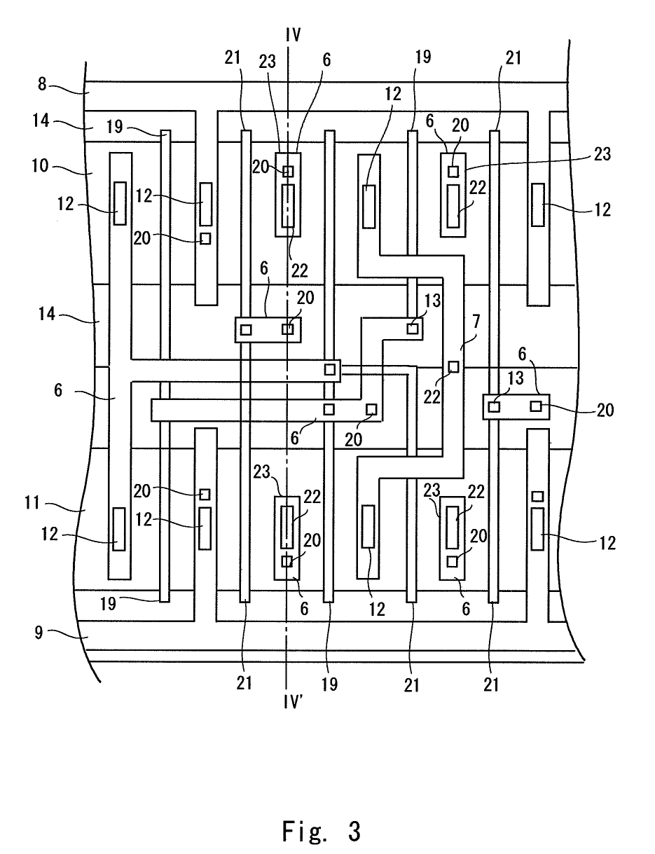

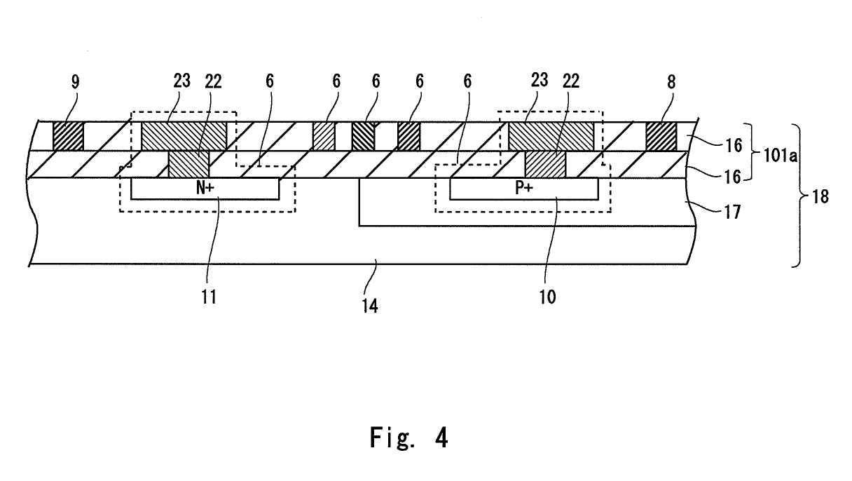

Referring now to FIGS. 3 and 4, an example of the structure of the semiconductor device to which the present invention is applied will be described. FIG. 3 is a plan view of the semiconductor device, and FIG. 4 is a cross sectional view taken along the line IV-IV′ in FIG. 3. The semiconductor device shown in FIGS. 3 and 4 shows a state in which the common wiring layer 101a is provided on the above-described basic element layer, and only includes the underlying layer before the step of forming the customize layer and the common wiring layer 101b.

As shown in FIG. 4, nodes 6, an output terminal 7, a power supply line 8, a ground line 9, a contact 12, a gate contact 13, a common wiring layer 15, a gate polysilicon 19, a via 20, a contact 22, and a wiring 23 are arranged and formed on the substrate 14.

As shown in FIG. 4, an N-type diffusion layer 11 and a P-type diffusion layer 10 are formed in the substrate 14. An N well 17 is formed around the P-type diffusion layer 10. An insulation film 16 is formed on the substrate 14. The contact 22 connected to the wiring 23 is formed in the upper surface of the N-type diffusion layer 11 and the P-type diffusion layer 10. The node 6 is formed by the N-type diffusion layer 11, the contact 22, and the wiring 23. The node 6 is also formed by the P-type diffusion layer 10, the contact 22, and the wiring 23.

The layer shown by the reference number 15 in FIG. 4 is the common wiring layer 101a, where the power supply line 8, the ground line 9, the nodes 6, the contact 22, and the wiring 23 are formed. Especially, the nodes 6 are arranged in the uppermost layer of the common wiring layer 101a to be connected to the wiring provided in the customize layer. However, not every node 6 is connected to the wiring in the customize layer but only the nodes 6 required to form the user circuit are connected. Therefore, in the structured ASIC, extra nodes 6 which are not connected to the customize layer are provided in the common wiring layer 101a. The layer shown by the reference numeral 18 in FIG. 4 is the underlying layer.

### Second Exemplary Embodiment

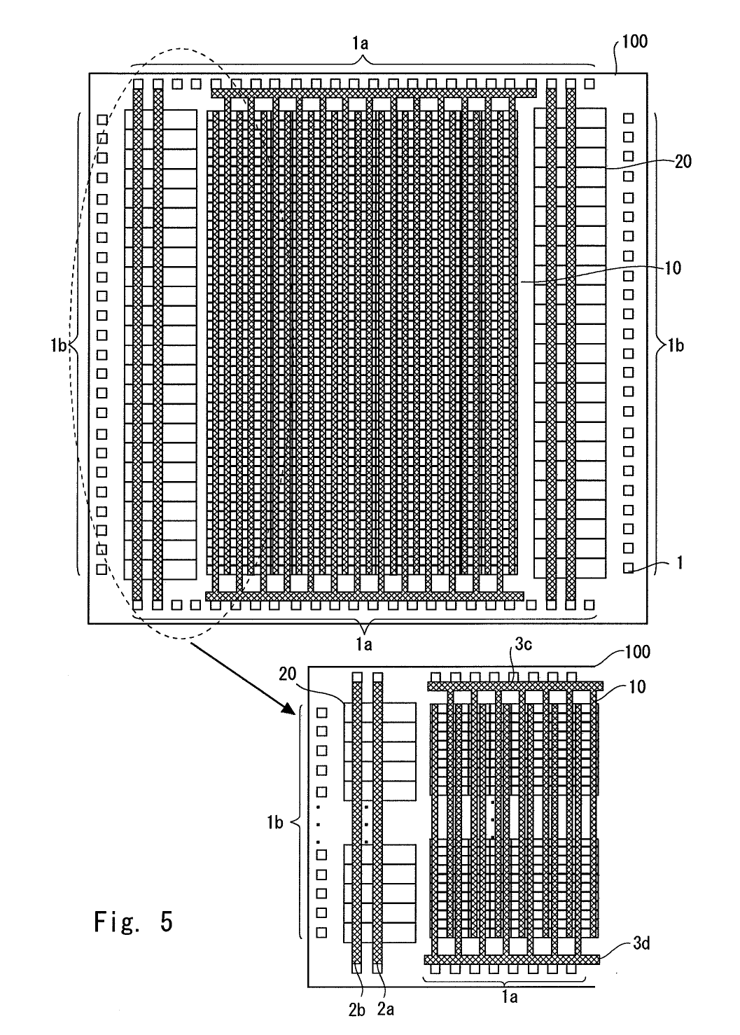

A semiconductor device according to the second exemplary embodiment has a different wiring pattern from that of the first exemplary embodiment of the present invention. FIG. 5 shows a top view of the semiconductor device according to the second exemplary embodiment. As shown in the drawing, in the semiconductor device according to the second exemplary embodiment, the power supply pads 1a are arranged in two sides opposed to each other (top and bottom sides in the drawing), and the input/output pads 1b are arranged in the remaining two sides opposed to each other (left and right sides in the drawing) in the chip 100. The input/output buffer is not provided in the side where the power supply pads 1a are arranged.

An internal power supply line 3c (power supply line) of comb-tooth shape is provided in one side having the power supply pads 1a, and an internal power supply line 3d (ground line) of comb-tooth shape is provided in the opposing side. In each of the internal power supply lines 3c and 3d, a plurality of linear wiring patterns are extended in parallel with each other from the linear wiring patterns extended in the arrangement direction of the power supply pads 1a in a direction perpendicular to the arrangement direction (the inner side direction of the chip 100) so as to connect the power supply pads 1a arranged in one direction with each other. Then the wiring patterns extended from one side and the wiring patterns extended from the opposite side are alternately arranged. In such a wiring pattern, the internal power supply line 3c which is the power supply line and the internal power supply line 3d which is the ground line are alternately arranged in parallel; therefore, the power can be supplied without increasing the length of the wiring in any position of the internal circuit region.

A power supply line for input/output buffer 2a (power supply line) and a power supply line for input/output buffer 2b (ground line) linearly coupling the power supply pads 1a in the opposing sides are arranged in the input/output buffer region 20.

As described above, in the second exemplary embodiment, the input/output buffer region 20 is arranged in two sides of the chip, and the power supply pads are arranged in the rest of the two sides; accordingly, the power supply pins added according to the power consumption of the circuit are not needed. Further, the first and second exemplary embodiments can be combined as desirable by one of ordinary skill in the art.

While the invention has been described in terms of several exemplary embodiments, those skilled in the art will recognize that the invention can be practiced with various modifications within the spirit and scope of the appended claims and the invention is not limited to the examples described above.

Further, the scope of the claims is not limited by the exemplary embodiments described above.

Furthermore, it is noted that, Applicant's intent is to encompass equivalents of all claim elements, even if amended later during prosecution.

What is claimed is:

1. A semiconductor integrated circuit comprising:
a first common wiring layer common to a plurality of types of products and independent of a user circuit;
a second common wiring layer common to a plurality of types of products and independent of the user circuit, and formed above an upper layer of the first common wiring layer; and
a customized layer provided between the first common wiring layer and the second common wiring layer and which is configured to form the user circuit,
wherein an universal logic cell is wired to the first and second common wiring layers and the customized layer,
wherein a power supply wiring, which is connected to a power supply pad, which is connected to an external power supply, is formed through the second common wiring layer, and
wherein the power supply wiring is formed in the same layer as the power supply pad and extends to an internal circuit area in which the universal logic cell is formed.

2. The semiconductor integrated circuit according to claim 1, wherein the power supply wiring is formed in the uppermost layer of the second wiring layer.

3. The semiconductor integrated circuit according to claim 1, wherein the second power supply wiring is connected to an internal circuit in the internal circuit area.

4. The semiconductor integrated circuit according to claim 1, wherein the semiconductor integrated circuit is formed as a chip, and includes an input/output pad in a peripheral area of a first side of the chip, and the power supply pad is provided in a peripheral area of a second side.

5. The semiconductor integrated circuit according to claim 1, wherein the semiconductor integrated circuit is formed as a chip and wherein input/output pads are provided in peripheral areas of a first and second sides of the chip and power supply pads are provided in on third and forth sides of the chip.

6. The semiconductor integrated circuit according to claim 1, wherein the semiconductor integrated circuit is formed as a chip, and power supply pads are provided on each of two opposed sides of the chip and are connected by the power supply wiring.

7. The semiconductor integrated circuit according to claim 1, wherein a ground wire is formed in the second common wiring layer, is connected to a ground pad, is formed in the same layer as the ground pad and extends to the internal circuit area in which the universal logic cell is formed.

8. The semiconductor integrated circuit according to claim 7, wherein the semiconductor integrated circuit is formed as a chip,
wherein the power supply pad is formed in a peripheral area of a first side of the chip, and the ground pad is formed in a peripheral area of second side of the chip, the second side of the chip is opposite the first side of the chip, and
wherein the power supply wire and the ground wire have comb shapes, which are alternatingly interspaced.

9. The semiconductor integrated circuit according to claim 1, wherein a wire width of the first common wiring layer is narrower than that of the second common wiring layer.

10. The semiconductor integrated circuit according to claim 2, wherein a wire width of the first common wiring layer is narrower than that of the second common wiring layer.

11. The semiconductor integrated circuit according to claim 3, wherein a wire width of the first common wiring layer is narrower than that of the second common wiring layer.

12. The semiconductor integrated circuit according to claim 4, wherein a wire width of the first common wiring layer is narrower than that of the second common wiring layer.

13. The semiconductor integrated circuit according to claim 5, wherein a wire width of the first common wiring layer is narrower than that of the second common wiring layer.

14. The semiconductor integrated circuit according to claim 6, wherein a wire width of the first common wiring layer is narrower than that of the second common wiring layer.

15. The semiconductor integrated circuit according to claim 7, wherein a wire width of the first common wiring layer is narrower than that of the second common wiring layer.

16. The semiconductor integrated circuit according to claim 8, wherein a wire width of the first common wiring layer is narrower than that of the second common wiring layer.

17. The semiconductor integrated circuit according to claim 9, wherein a wire width of the first common wiring layer is less than half of that of the second common wiring layer.
